(19) United States
(12) Patent Application Publication
(10) Pub. No.: US 2016/0108516 A1
(43) Pub. Date: Apr. 21, 2016

(54) METHOD OF APPLYING METALLIC LAYER ON SUBSTRATE AND COMPOSITE ARTICLE FORMED THEREBY

(71) Applicant: DM3D TECHNOLOGY, LLC, Auburn Hills, MI (US)

(72) Inventor: Bhaskar Dutta, Troy, MI (US)

(21) Appl. No.: 14/885,369

(22) Filed: Oct. 16, 2015

Related U.S. Application Data
(60) Provisional application No. 62/065,144, filed on Oct. 17, 2014.

(51) Int. Cl. C23C 16/06; C23C 16/44; C23C 14/22; C23C 4/12; C23C 24/04

(52) U.S. Cl. CPC C23C 16/06; C23C 4/12; C23C 24/04; C23C 14/22; C23C 16/44

(57) ABSTRACT

A method of preparing a composite article is disclosed. The method comprises the step of providing a substrate having a melting point temperature T¹. The method additionally comprises the step of forming a buffer layer having a melting point temperature T² on the substrate. Finally, the method comprises the step of forming a metallic layer having a melting point temperature T³ on the buffer layer to prepare the composite article. In the method to prepare the composite article, T¹<T²<T³.

### CROSS-REFERENCE TO RELATED APPLICATIONS

This application claims priority to and all advantages of U.S. Application Ser. No. 62/065,144, filed on Oct. 17, 2014, the content of which is hereby incorporated by reference.

### FIELD OF THE INVENTION

The present invention generally relates to a method of preparing a composite article and, more specifically, to a method of preparing a composite article including a metallic layer and to the composite article formed thereby.

### DESCRIPTION OF THE RELATED ART

Methods of adjoining materials are known in the art and may take a variety of forms depending on the materials to be joined. Materials may be chemically bonded and/or physically bonded to one another. For example, metals or alloys may be adjoined via welding or other similar techniques. Alternatively, adhesives may be utilized to bond materials.

However, adjoining materials is increasingly difficult when the materials are substantially different from one another, e.g. in terms of physical and/or mechanical properties. For example, plastics and metals are generally incompatible with one another, and thus bonding plastics and metals often necessitates various adhesives, which may fail or degrade over time. Similarly, different types of metals and alloys may have significantly different properties from one another, including melting point temperatures, which result in difficulty in working with molten or heated metals and substrates having low melting point temperatures. As but one example, certain steel alloys have a melting point temperature of about 1427° C., whereas certain zinc alloys may have melting point temperatures more than 1000° C. less, e.g. of about 396° C. This difference in melting point temperatures significantly limits the ability to process such materials together.

### SUMMARY OF THE INVENTION

The present invention provides a method of preparing a composite article.

The method comprises the step of providing a substrate having a melting point temperature T¹. The method additionally comprises the step of forming a buffer layer having a melting point temperature T² on the substrate. Finally, the method comprises the step of forming a metallic layer having a melting point temperature T³ on the buffer layer to prepare the composite article. In the method to prepare the composite article, T¹<T²<T³.

### DETAILED DESCRIPTION OF THE INVENTION

The present invention provides a method of preparing a composite article and the composite article formed thereby. The inventive method is particularly well suited for preparing composite articles having a melting point temperature gradient through a thickness thereof and allows for use of substrates that otherwise cannot be utilized with metallic layers. For example, the inventive method is suitable for adjoining materials having significantly different melting point temperatures from one another. However, the inventive method is not so limited and may be utilized to prepare composite articles comprising materials similar to one another.

The method comprises the step of providing a substrate. The substrate has a melting point temperature T¹. T¹ is not limited and is typically dependent on the material of the substrate. The substrate has a melting point temperature that is less than the melting point temperature of other layers of the composite article.

In certain embodiments, the substrate comprises a metal or alloy. Specific examples of metals suitable for use as the substrate include zinc, antimony, tin, bismuth, indium, cadmium, gallium, aluminum, etc., along with combinations thereof or alloys including one or more of these metals.

In other embodiments, the substrate comprises a polymeric material. The polymeric material is not limited and may be a thermosetting material or a thermoplastic material. The substrate may be formed, e.g. by polymerizing monomers, or may be provided or obtained. In certain embodiments, the polymer material of the substrate is selected from the group of polycarbonates, polyamides (e.g. nylon 6, nylon 66, etc.), polyimides, polysulfones, polyesters (e.g. polyethylene terephthalate, polyethylene naphthalate, etc.), polyolefins (polyethylene, polypropylene, etc.), polynorbornenes, (meth)acrylic polymers (e.g. acrylics, (meth)acrylics, thio(meth)acrylics, etc.), epoxy polymers, episulfide polymers, polystyrenes, celluloses (e.g. triacetylcellulose, diacetylcellulose, cellophane, etc.), poly(vinyl chlorides), poly(vinyl alcohols), poly(ethylene vinyl alcohols), polyacetylenes, polyarylenes, polyarylene vinylenes, polyarylene ethynylenes, polyurethanes, or an interpolymer thereof.

When the substrate comprises the polymeric material, the substrate may also comprise or contain various additives or fillers to impact physical properties of the substrate. For example, the substrate may comprise a filler selected from aluminum nitride, aluminum oxide, aluminum trihydrate, barium titanate, beryllium oxide, boron nitride, carbon fibers, diamond, graphite, magnesium hydroxide, magnesium oxide, metal particulate, onyx, silicon carbide, tungsten carbide, zinc oxide, and a combination thereof.

Alternatively or in addition, when the substrate comprises the polymeric material, metallic fillers may be included, which include particles of metals and particles of metals having layers on the surfaces of the particles may be utilized. Suitable metallic fillers are exemplified by particles of metals selected from the group consisting of aluminum, copper, gold, nickel, silver, and combinations thereof, and alternatively aluminum. Suitable metallic fillers are further exemplified by particles of the metals listed above having layers on their surfaces selected from the group consisting of aluminum nitride, aluminum oxide, copper oxide, nickel oxide, silver oxide, and combinations thereof. For example, the metallic filler may comprise aluminum particles having aluminum oxide layers on their surfaces.

Alternatively or in addition, when the substrate comprises the polymeric material, meltable fillers may be included. Examples of meltable fillers include Bi, Ga, In, Sn, or an alloy thereof. The meltable filler may optionally further comprise Ag, Au, Cd, Cu, Pb, Sb, Zn, or a combination thereof. Examples of suitable meltable fillers include Ga, In—Bi—Sn alloys, Sn—In—Zn alloys, Sn—In—Ag alloys, Sn—Ag—Bi alloys, Sn—Bi—Cu—Ag alloys, Sn—Ag—Cu—Sb alloys, Sn—Ag—Cu alloys, Sn—Ag alloys, Sn—Ag—Cu—Zn alloys, and combinations thereof. The meltable filler may have a melting point ranging from 50° C. to 250° C., alternatively 150° C. to 225° C. The meltable filler may be a eutectic alloy, a non-eutectic alloy, or a pure metal.

Alternatively or in addition, the substrate may comprise inorganic fillers in particulate form, such as silica, alumina, calcium carbonate, and mica. In one embodiment, for example, the first and/or second electrode layers include silica particles, e.g. silica nanoparticles. One particularly useful form of silica nanoparticles are fumed silica nanoparticles.

Alternatively or in addition, the substrate may comprise at least one filler which is exemplified by reinforcing and/or extending fillers, such as alumina, calcium carbonate (e.g., fumed, ground, and/or precipitated), diatomaceous earth, quartz, silica (e.g., fumed, ground, and/or precipitated), talc, zinc oxide, chopped fiber such as chopped KEVLAR®, or a combination thereof.

Regardless of whether the substrate comprises the metal or alloy or the polymeric material, the substrate may have any shape and dimension depending on a desired geometry of the composite article. The substrate may be modified to a desired geometry prior to forming a buffer layer thereon. For example, the substrate may be machined to a desired shape, size, configuration, and/or surface roughness. The desired geometry of the substrate may or may not be similar or identical to the desired geometry of the composite article. For example, part geometry and surface specifications may vary between the substrate and the composite article, or they may be the same.

The method further comprises forming a buffer layer on the substrate. The buffer layer has a melting point temperature T², and T¹<T². The buffer layer may be referred to as a tie layer and allows the formation of a metallic layer thereon to give the composite article, as described below. For example, when the substrate comprises the polymeric material, the buffer layer is physically and/or chemically bonded to the substrate. When the substrate comprises the metal or alloy, the buffer layer may be metallurgically bonded to the substrate.

The metallic layer is formed on the buffer layer. As such, the inventive method is particularly suited to form composite articles comprising polymeric materials and metals, which generally are incompatible with one another. In addition, the inventive method is particularly suited to form composite articles comprising metals or alloys having different melting point temperatures from one another without conventional drawbacks associated therewith.

The buffer layer may comprise two or more layers which together may be referred to singularly as the buffer layer. For example, the buffer layer may comprise a plurality of layers, which may be distinct or indistinct. When the buffer layer comprises two or more layers, each successive layer outwardly from the substrate has an increased melting point temperature, as described below.

As one example, in one embodiment, the buffer layer comprises at least a first buffer layer having a melting point temperature T^{2a} disposed on the substrate and a second buffer layer having a melting point temperature T^{2b} disposed on the first buffer layer, wherein T^{2a}<T^{2b}. Because the substrate has a melting point temperature T¹, T¹<T^{2a}<T^{2b}. When the buffer layer comprises the first buffer layer and the second buffer layer, the method comprises forming the first buffer layer on the substrate and forming the second buffer layer on the first buffer layer.

As another example, the step of forming the buffer layer comprises forming a plurality of sequential layers disposed on one another outwardly from the substrate. In this embodiment, each of the sequential layers has a melting point temperature which is between the melting point temperatures of adjacent layers such that each of the plurality of sequential layers has an increased melting point temperature outwardly from the substrate. In this embodiment, the buffer layer may comprise 3, 4, 5, 6, 7, 8, 9, 10 or more layers which together are referred to as the buffer layer, particularly when the substrate has a low melting point temperature. Each of the layers of the buffer layer may be independently physically and/or chemically bonded to one another.

The buffer layer may be formed on the substrate via any known method, which is generally dictated in part based on the material utilized to form the buffer layer. When the buffer layer comprises a plurality of layers, each of the plurality of layers may be independently formed via independently selected techniques. For clarity and consistency, reference below to formation of the buffer layer may refer to the formation of any specific sequential layer of the buffer layer or a portion of the buffer layer, particularly when the buffer layer comprises the plurality of sequential layers.

In certain embodiments, the buffer layer comprises the polymeric material. The polymeric material of the buffer layer may be selected from any of those described above with reference to the substrate, so long as T¹<T². As such, the polymeric material of the buffer layer and the substrate, if each comprises the polymeric materials, are typically independently selected. Alternatively, the buffer material may comprise a metal or alloy. Specific examples buffer materials suitable for forming the buffer layer when the buffer layer comprises the metal or alloy include, but are not limited to, steel, nickel, copper, and any combinations or alloys thereof. Alternatively still, the buffer layer may comprise the polymeric material in combination with the metal or alloy, e.g. when the buffer layer comprises two or more layers. In these embodiments, because the melting point temperature of the composite article increases outwardly from the substrate, the polymeric materials of the buffer layer are typically adjacent the substrate whereas the metal or alloy layer(s) are outermost layers with respect to the buffer layer.

The buffer layer may comprise both the polymeric material and the metal or alloy. For example, as noted above, the buffer layer may comprise a plurality of sequential layers. In certain embodiments, the sequential layer disposed on and adjacent the substrate comprises the polymeric material. Additional sequential layers may be formed on the sequential layer on the substrate. Typically, at least an outermost portion of the buffer layer comprises the metal or alloy.

The buffer layer may be formed by applying a buffer material on the substrate to form the buffer layer. The buffer material may comprise a buffer composition which may be applied via a wet form or dry form.

For example, in certain embodiments, the step of forming the buffer layer uses a wet coating application method, particularly when the buffer layer comprises the polymeric material. Specific examples of wet coating application methods suitable for the method include dip coating, spin coating, flow coating, spray coating, roll coating, gravure coating, sputtering, slot coating, inkjet printing, and combinations thereof. In these embodiments, the buffer layer is typically formed from the buffer composition, which may additionally include a carrier vehicle for the polymeric material. The carrier material may be driven from the substrate to give the buffer layer via the application of heat, if desired.

In certain embodiments, forming the buffer layer comprises applying a buffer material via a non-thermal process on the substrate to form the buffer layer. One example of such a non-thermal spraying process is a kinetic spraying process. In these embodiments, the buffer material is generally applied as a liquid or particulate material on the substrate or on the sequential layer already disposed on the substrate. Depending on a selection of the substrate, the substrate may undergo plastic deformation upon coming into contact with the buffer material when forming the buffer layer, particularly when T¹<T² and when the substrate comprises the polymeric material

Alternatively or in addition, the buffer layer may be formed via a deposition apparatus. For example, when the deposition apparatus is utilized, the deposition apparatus typically comprises a physical vapor deposition (PVD) apparatus. In these embodiments, the deposition apparatus is typically selected from a sputtering apparatus, an atomic layer deposition apparatus, a vacuum apparatus, and a DC magnetron sputtering apparatus. The optimum operating parameters of each of these physical deposition vapor apparatuses are based upon the buffer material utilized, the substrate on which the buffer layer is to be formed, etc. In certain embodiments, the deposition apparatus comprises a vacuum apparatus. In other embodiments, the deposition apparatus is a chemical vapor deposition apparatus (CVD). Alternatively or in addition, thermal spray and/or laser cladding may be utilized to form the buffer layer.

When the substrate comprises the polymeric material, the buffer layer may comprise a first polymeric material disposed on the substrate, optionally a second polymeric material disposed on the first polymeric material, optionally a third polymeric material disposed on the second polymeric material, and so on. The buffer layer may further comprise a metal or alloy on the particular polymeric material. In this manner, the melting point temperature of each sequential layer of the composite article increases incrementally outwardly from the substrate, which minimizes a difference in melting point temperatures between the substrate and the metallic layer, thereby minimizing plastic deformation and other drawbacks associated with the deposition of metals on polymeric materials.

In certain embodiments, each sequential layer has a melting point temperature that is at least 10, 15, 20, 25, 30, 35, or 40° C. greater than the melting point temperature of the previous layer (outwardly from the substrate).

When the buffer layer comprises first and second metal layers, the second metal layer may be formed on the first metal layer via a direct-metal deposition process. Specific aspects of the direct-metal deposition process are disclosed in U.S. Pat. No. 6,122,564, which is incorporated by reference herein in its entirety. The buffer layer may comprise the first and second metal layers in combination with other or additional metal layers and/or other or additional layers comprising polymeric materials. The direct-metal deposition process may be utilized for any two adjacent layers which comprise metals or alloys.

In the direct-metal deposition process, a laser beam of a controllable laser is directed to a region of the first metal layer to form a melt pool in the region with the laser beam. The melt pool may alternatively be referred to as a weld pool. A metallic material is fed into the melt pool to be melted by the laser beam. The second metal layer is formed with the metallic material and the laser beam on the first metal layer. The metallic material is typically in the form of a powder or wire. Wire may be fed into the laser beam as an alternative to dispensing powder and an electron beam may be used as an alternative to the laser beam.

More specifically, in certain embodiments, a laser source is mounted above the substrate or workpiece (including the first metal layer) in order to focus the laser beam thereon. The workpiece may be carried on a work table, though any number of arrangements may be used to cause relative movement between the workpiece and a laser spray nozzle. The laser source is typically a continuous-wave or pulse CO₂, YAG, diode, fiber or any other wavelength laser having a power density enough to melt the material to be deposited. Typically, an RF-excited laser, high-power CO₂ laser or high-power diode laser is used. The laser beam is generally directed in a direction roughly perpendicular to the surface of the workpiece.

The controllable laser may include a nozzle assembly. The laser and nozzle assemblies are not limited. Specific examples of suitable laser and nozzle assemblies are described in U.S. Pat. Nos. 5,241,419, 5,453,329, and 5,477,026 which are each incorporated by reference herein in their respective entireties. A suitable laser spray nozzle is available from Quantum Laser Corporation of Norcross, Ga., and is as described in U.S. Pat. No. 4,724,299, which is also incorporated by reference herein in its entirety.

In certain embodiments, the spray nozzle provides a common outlet for the beam and the powder so that both are consistently directed at the same point on the workpiece. In these embodiments, the spray nozzle achieves uniform clad composition because the laser beam exits the spray nozzle substantially coaxially with the cladding powder, both having the same focal point. The spray nozzle has a common outlet for the laser beam and the power so that both are consistently directed at the same point on the workpiece. In this way, a common focal point is achieved which assures uniform clad composition. Similar results can also be obtained by side injection nozzle.

Conventional laser cladding techniques may move the first metal layer relative to the laser beam focal point through the use of jigs, parts handlers and the like. The laser beam focal point therefore remains fixed in space, as does the position of the powder stream. Robots may also be utilized, which may be powered electrically, hydraulically or pneumatically, or through some combination of these means. Utilization of a robot in conjunction with a laser cladding system helps toward means for achieving a uniform clad. The first metal layer may remain fixed in space and the nozzle may therefore move relative to the first metal layer in cooperation with movement of the robot. Alternatively, the nozzle may remain fixed and the first metal layer may be moved by the robot.

In the direct-metal deposition process, the laser spray nozzle forms a melt-pool on the first metal layer. Typically, in contrast to a Gaussian profile, the midpoint of the laser beam profile has a lower intensity. This provides a melt-pool of relatively uniform temperature distribution. However, other spatial distributions of the laser beam can be adapted for the process.

The laser beam is typically controlled by accepting direction from a CAD/CAM computer. A feedback control device may also be utilized, optionally in combination with an optical monitoring system. In this way, a dimension such as the height of a melt pool may be monitored optically and controlled electronically. The high temperature of the melt pool emits with intensity in the infrared region.

For example, the controllable laser is typically part of a system including an optoelectric sensor to output an electrical signal as a function of a height of the second metal layer formed with the laser beam. In these embodiments, the method further comprises adjusting a rate of feeding the metallic material into the melt pool as a function of the electrical signal of the optoelectric sensor. Additional aspects associated with the system are disclosed and incorporated herein via U.S. Pat. No. 6,122,564.

Finally, the invention comprises forming a metallic layer having a melting point temperature T³ on the buffer layer to prepare the composite article. T³>T²>T¹. The metallic layer is an outermost layer of the composite article and has the greatest melting point temperature of the layers of the composite article.

As introduced above, the buffer layer may comprise a plurality of sequential layers. In these embodiments, an outermost layer of the buffer layer is typically a metal or alloy, e.g. steel, nickel, copper, and any combinations or alloys thereof. When the buffer layer comprises but one single layer, the buffer layer typically also comprises the metal or alloy. As such, the formation of the metallic layer on the buffer layer is typically a metal-on-metal process. Further, when the substrate comprises a metal or alloy, the process is a metal-on-metal process throughout the various steps of forming the composite article.

The metallic layer may be formed on the buffer layer via any known method. The metallic layer is distinguished from the buffer layer, at least with respect to melting point temperature. However, the metallic layer and the buffer layer may comprise the same types of metals, but in different relative amounts, so as to influence the melting point temperature gradient of the composite article.

In certain embodiments, the metallic layer comprises steel, including steels comprising hardening agents other than iron and carbon, Inconel® alloys, Stellite® alloys, etc. When both the buffer material and the metallic layer comprise steel, the buffer material and the metallic layer are generally distinguished from one another, e.g. in atomic structure or elemental composition. As known in the art, Inconel® alloys comprise austenitic nickel-chromium-based alloys, whereas Stellite® alloys comprise cobalt-chromium alloys. Such metallic layers may include other metals as well, e.g. tungsten, molybdenum, etc. Inconel® is owned by Special Metals Corporation of New Hartford, N.Y., and Stellite® is owned by Kennametal Stellite of Goshen, Ind.

The metallic layer may be formed on the buffer layer via any suitable technique, e.g. thermal and/or chemical processes, including kinetic spray, thermal spray, PVD, CVD, laser cladding, etc. Because forming the metallic layer on the buffer layer is a metal-on-metal process, the step of forming the metallic layer on the buffer layer typically comprises forming the metallic layer on the buffer layer via a direct-metal deposition process. The formation of the metallic layer on the buffer layer may complete the build-up of fine features to create near-net shape geometry of the composite article.

The direct-metal deposition process is introduced and described above with reference to the first and second metal layers of the buffer layer. The direct-metal deposition process and associated system may vary in connection with each step or layer of the inventive method and composite article. The direct metal deposition process comprises directing a laser beam of a controllable laser to a region of the buffer layer to form a melt pool in the region with the laser beam. The direct-metal deposition process further comprises feeding a metallic material into the melt pool to be melted by the laser beam. The metallic material is typically a powder or wire. Finally, the direct-metal deposition process comprises forming the metallic layer with the metallic material and the laser beam.

The controllable laser may be part of a system including an optoelectric sensor to output an electrical signal as a function of a height of the metallic layer. In this embodiment, the system may include a feedback controller and the method may further comprise adjusting a rate of feeding the metallic material into the melt pool as a function of the electrical signal of the optoelectric sensor.

During the direct-metal deposition process, a size or temperature of the melt pool may be sensed via an image, or alternatively a pyrometer, and the sensed value is provided to a numerical processor which adjusts the process laser power. This may be referred to as a feedback mechanism or closed-loop control mechanism, as disclosed in U.S. Pat. No. 8,878,094, which is incorporated by reference herein in its entirety.

When the formation of the buffer layer does not employ the direct-metal deposition process, the feedback mechanism may not be utilized during the formation of the metallic layer on the buffer layer, as the formation of the metallic layer is the first direct-metal deposition process and thermal conduction conditions and associated parameters will differ substantially from those for subsequently deposited layers. However, if the formation of the metallic layer is at least the second direct-metal deposition process utilized in the inventive method, a number of test point coordinates may be selected along the layer surface. The number of test points considered depends on the area of deposition, the part geometry, and the processing speed of the CPU running the algorithm. As each subsequent layer is deposited via the direct-metal deposition process, the pool size or temperature for each test point is sensed and stored. The weld pool size and temperature are closely related to one another. This layer may be termed the “Golden Layer” since the values for the pool size or temperature measured at each test point during the deposition of this layer are considered the target values for the deposition parameters at corresponding test point coordinates in subsequently deposition layers.

Use of and reliance on the Golden Layer is described in more detail in U.S. Pat. No. 8,878,094. Generally, measurements are made of the weld size at the same selected coordinates as successive layers are formed and the measurements of weld size at a particular layer will be processed in connection with the stored matrices representing the weld sizes at previous layers to determine a suitable laser power for use in the deposition of the next layer. These power adjustments from layer to layer are broadly intended to compensate for effects of heating of the substrate on the weld pool size.

The weld pool image is the basic input for the control system and contains temperature information relating to the weld pool. Weld pool temperature information is extracted from the weld pool image by determining the image brightness level and its area and is called “weld pool size.” By controlling the laser power, the weld pool size is controlled and hence the weld pool temperature, thus making a closed-loop feedback system. The system is made self-learning or adaptive by applying the previous layer image information to future layer laser power corrections.

The composite article is provided by forming the metallic layer on the buffer layer. The metallic layer may be physically and/or chemically bonded to the buffer layer. There may not be distinct layers in the composite article, particularly if the buffer layer partially melts upon the formation of the metallic layer thereon, in which case an alloy or eutectic system may form at an interface between the metallic layer and the buffer layer.

If desired, the metallic layer and/or the composite article may undergo a further treatment process, e.g. for stress-relief or an alternative heat treating process, following the formation of the metallic layer. If desired, the composite article, or any portion thereof (i.e., the substrate, the buffer layer, and/or the metallic layer) may be modified to a desired geometry. For example, the composite article, or any portion thereof (i.e., the substrate, the buffer layer, and/or the metallic layer) may be machined, e.g. by CNC machining, manual machining, grinding, and/or EDM milling.

The composite article may have various dimensions and geometries depending on a desired end use thereof. In various embodiments, the buffer layer has a thickness of from greater than 0 to 100, alternatively from greater than 0 to 50, alternatively from greater than 0 to 10, alternatively from 0.2 to 6, millimeters. In these or other embodiments, the metallic layer has a thickness of from greater than 0 to 100, alternatively from greater than 0 to 50, alternatively from greater than 0 to 10, alternatively from 0.5 to 6, millimeters. It is to be appreciated that the thicknesses of the buffer layer and the metallic layer may deviate from the ranges set forth immediately above depending on an end use of the composite article.

The inventive method and resulting composite article may be utilized in a variety of end use applications and industries. For example, the inventive method may be utilized to convert soft tooling to production tooling. Further, the inventive method allows for the application of high melting point metals, such as steel, onto materials which have lesser melting point temperatures, including other metals, without uncontrolled melting and deformation of the materials having lesser melting point temperatures.

It is to be understood that the appended claims are not limited to express and particular compounds, compositions, or methods described in the detailed description, which may vary between particular embodiments which fall within the scope of the appended claims. With respect to any Markush groups relied upon herein for describing particular features or aspects of various embodiments, different, special, and/or unexpected results may be obtained from each member of the respective Markush group independent from all other Markush members. Each member of a Markush group may be relied upon individually and or in combination and provides adequate support for specific embodiments within the scope of the appended claims.

Further, any ranges and subranges relied upon in describing various embodiments of the present invention independently and collectively fall within the scope of the appended claims, and are understood to describe and contemplate all ranges including whole and/or fractional values therein, even if such values are not expressly written herein. One of skill in the art readily recognizes that the enumerated ranges and subranges sufficiently describe and enable various embodiments of the present invention, and such ranges and subranges may be further delineated into relevant halves, thirds, quarters, fifths, and so on. As just one example, a range “of from 0.1 to 0.9” may be further delineated into a lower third, i.e., from 0.1 to 0.3, a middle third, i.e., from 0.4 to 0.6, and an upper third, i.e., from 0.7 to 0.9, which individually and collectively are within the scope of the appended claims, and may be relied upon individually and/or collectively and provide adequate support for specific embodiments within the scope of the appended claims. In addition, with respect to the language which defines or modifies a range, such as “at least,” “greater than,” “less than,” “no more than,” and the like, it is to be understood that such language includes subranges and/or an upper or lower limit. As another example, a range of “at least 10” inherently includes a subrange of from at least 10 to 35, a subrange of from at least 10 to 25, a subrange of from 25 to 35, and so on, and each subrange may be relied upon individually and/or collectively and provides adequate support for specific embodiments within the scope of the appended claims. Finally, an individual number within a disclosed range may be relied upon and provides adequate support for specific embodiments within the scope of the appended claims. For example, a range “of from 1 to 9” includes various individual integers, such as 3, as well as individual numbers including a decimal point (or fraction), such as 4.1, which may be relied upon and provide adequate support for specific embodiments within the scope of the appended claims.

The following examples are intended to illustrate the invention and are not to be viewed in any way as limiting to the scope of the invention.

### EXAMPLES

### Example 1

A substrate is provided which comprises cast iron having a melting point temperature T¹ of about 1,200° C. Steel having a melting point temperature T³ of about 1,427° C. is desired to be applied adjacent the substrate to form a metallic layer. However, given the difference between T¹ and T³, the metallic layer cannot be applied to the substrate in molten form without impacting characteristics of the substrate.

A buffer layer is first formed on the substrate. The buffer layer comprises Inconel® 625, commercially available from Special Metals Corporation of New Hartford, N.Y. The buffer layer is a nickel-chromium alloy having a melting point temperature T² of about 1,350° C.

The buffer layer is formed on the substrate via a direct-metal deposition process. In particular, the buffer layer is formed on the substrate by directing a laser beam of a controllable laser to a region of the substrate to form a melt pool in the region with the laser beam. The nickel-chromium alloy utilized to form the buffer layer is fed into the melt pool to be melted by the laser beam. The buffer layer is formed with the nickel-chromium alloy and the laser beam.

After formation of the buffer layer on the substrate, the metallic layer is formed on the buffer layer in the same manner, i.e., the direct-metal deposition process. However, the steel is fed to into the melt pool formed in the region of the buffer layer when forming the metallic layer. After forming the metallic layer on the buffer layer, a composite article results, including the substrate having the melting point temperature T¹, the buffer layer having the melting point temperature T², and the metallic layer having the melting point temperature T³, wherein T¹<T²<T³. The use of the buffer layer minimized the incremental difference in melting point temperatures between the substrate and the metallic layer.

### Example 2

A substrate is provided which comprises an aluminum alloy having a melting point temperature T¹ of about 613° C. Steel having a melting point temperature T³ of about 1,427° C. is desired to be applied adjacent the substrate to form a metallic layer. However, given the difference between T¹ and T³, the metallic layer cannot be applied to the substrate in molten form without impacting characteristics of the substrate.

A buffer layer is first formed on the substrate. The buffer layer comprises a copper alloy having a melting point temperature T² of about 1,045° C.

The buffer layer is formed on the substrate via a direct-metal deposition process. In particular, the buffer layer is formed on the substrate by directing a laser beam of a controllable laser to a region of the substrate to form a melt pool in the region with the laser beam. The copper alloy utilized to form the buffer layer is fed into the melt pool to be melted by the laser beam. The buffer layer is formed with the copper alloy and the laser beam.

After formation of the buffer layer on the substrate, the metallic layer is formed on the buffer layer in the same manner, i.e., the direct-metal deposition process. However, the steel is fed to into the melt pool formed in the region of the buffer layer when forming the metallic layer. After forming the metallic layer on the buffer layer, a composite article results, including the substrate having the melting point temperature T¹, the buffer layer having the melting point temperature T², and the metallic layer having the melting point temperature T³, wherein T¹<T²<T³. The use of the buffer layer reduced the significant difference in melting point temperatures between the substrate and the metallic layer.

The invention has been described in an illustrative manner, and it is to be understood that the terminology which has been used is intended to be in the nature of words of description rather than of limitation. Obviously, many modifications and variations of the present invention are possible in light of the above teachings. The invention may be practiced otherwise than as specifically described.

What is claimed is:

1. A method of preparing a composite article, said method comprising the steps of:
providing a substrate having a melting point temperature T¹;
forming a buffer layer having a melting point temperature T² on the substrate; and
forming a metallic layer having a melting point temperature T³ on the buffer layer to prepare the composite article;
wherein T¹<T²<T³.

2. The method of claim 1, wherein the buffer layer comprises metal and forming the metallic layer on the buffer layer comprises forming the metallic layer on the buffer layer via a direct-metal deposition process.

3. The method of claim 2, wherein the direct metal deposition process comprises:
directing a laser beam of a controllable laser to a region of the buffer layer to form a melt pool in the region with the laser beam;
feeding a metallic material into the melt pool to be melted by the laser beam; and
forming the metallic layer with the metallic material and the laser beam.

4. The method of claim 3 wherein the controllable laser is part of a system including an optoelectric sensor to output an electrical signal as a function of a height of the metallic layer.

5. The method of claim 4 wherein the system includes a feedback controller and wherein the method further comprises adjusting a rate of feeding the metallic material into the melt pool as a function of the electrical signal of the optoelectric sensor.

6. The method of claim 3 wherein the metallic material is a powder.

7. The method of claim 1 wherein the substrate comprises a polymeric material.

8. The method of claim 7 wherein the polymeric material is selected polycarbonates, polyamides, polyimides, polysulfones, polyesters, polyolefins, polynorbornenes, (meth)acrylic polymers, epoxy polymers, episulfide polymers, polystyrenes, celluloses, poly(vinyl chlorides), poly(vinyl alcohols), poly(ethylene vinyl alcohols), polyacetylenes, polyarylenes, polyarylene vinylenes, polyarylene ethynylenes, or an interpolymer thereof.

9. The method of claim 1 wherein the buffer layer comprises at least a first buffer layer having a melting point temperature T^{2a} disposed on the substrate and a second buffer layer having a melting point temperature T^{2b} disposed on the first buffer layer, and wherein T^{2a}<T^{2b}.

10. The method of claim 1 wherein forming the buffer layer comprises forming a plurality of sequential layers disposed on one another outwardly from the substrate, and wherein each of the sequential layers has a melting point temperature which is between the melting point temperatures of adjacent layers such that each of the plurality of sequential layers has an increased melting point temperature outwardly from the substrate.

11. The method of claim 10 wherein at least one of the sequential layers of the buffer layer is formed via a direct-metal deposition process.

12. The method of claim 10 wherein the plurality of sequential layers are formed via a direct-metal deposition process to give the buffer layer.

13. The method of claim 10 wherein at least one of the sequential layers of the buffer layer is formed via a kinetic spray process, a thermal spray process, physical vapor deposition, or chemical vapor deposition.

14. The method of claim 10 wherein at least the sequential layer disposed on the substrate comprises a polymeric material.

15. The method of claim 1 wherein the buffer layer comprises steel, nickel, or copper.

15. The method claim 1 wherein the metallic layer comprises steel.

16. A composite article formed in accordance with the method of claim 1.
